(19) United States
(12) Patent Application Publication
(10) Pub. No.: US 2011/0176301 A1
(43) Pub. Date: Jul. 21, 2011

(54) METHOD TO PRODUCE HOMOGENEOUS LIGHT OUTPUT BY SHAPING THE LIGHT CONVERSION MATERIAL IN MULTICHIP MODULE

(75) Inventors: Loke Chai Liang, Penang (MY); Sundar Yoganandan, Gelugor (MY); Chew Wui Chai, Penang (MY)

(73) Assignee: DSEM Holdings Sdn. Bhd., Penang (MY)

(21) Appl. No.: 13/010,368

(22) Filed: Jan. 20, 2011

(30) Foreign Application Priority Data
Jan. 21, 2010 (MY) PI2010000306

(51) Int. Cl. F21V 9/00; F21V 5/00; H01L 33/50

(52) U.S. Cl. 362/231; 362/235; 438/27; 257/E33.059

(57) ABSTRACT

A multichip module includes a series of light sources arranged in a planar array, separated by a distance d₁ in the x-direction and d₂ in the y-direction apart, or they could be spaced different distances apart which are mounted onto an aluminum oxide metal substrate. A uniform light transmissive layer being disposed over said series of light sources having a thickness t, measure from the top of the light sources. A phosphor resin being formed above this light transmissive layer. An encapsulant having a domed portion which functions as a lens, overlaying the phosphor resin to encapsulate the array of light sources. The light transmissive layer, phosphor resin layer and the encapsulant may be formed using an injection molding process.

### FIELD OF THE INVENTION

The invention relates to producing homogenous light output and fabricating methods of making the same in multichip module, and more particularly in shaping the light conversion layer and shaping methods for the light conversion layer.

### BACKGROUND

A light emitting die/chip is a semiconductor device that can efficiently emit bright colored light of monochromatic peak even though its size is small. As is well known to those skilled in the art, semiconductor device consists of more than one semiconductor layers that are configured to emit light upon energization thereof.

White light is important for a wide variety of application especially in the illumination market. To generate white light from light emitting diode (LED) in conventional LED lamp, one design is to position red, green and blue light emitting chips close to each other to enable light produced by the light emitting chips to mix together and generate white light. This conventional design of producing white light is not efficient as the color formed is uneven and at the same time costly.

In another class of prior art, a white emitting LED can be constructed by making an LED that emits a combination of blue and yellow light in the proper ratio of intensities. Yellow light can be generated from the blue light by converting some of the blue photons through an appropriate phosphor. In one design, a transparent layer containing yellow phosphor dispersed in the resin covers the blue light emitting chip that is mounted onto the reflector cup. The phosphor particles that are dispersed in a transparent layer surround the light-emitting surface of the blue light emitting chip. To obtain a white emitting LED, the thickness and uniformity of the dispersed phosphor particles must be tightly controlled.

With reference to FIG. 1, therein is shown a cross-sectional view of a light-emitting diode (LED) 100. The LED 100 has a first and second terminals, or lead frames 105 and 106, by which electrical power is supplied to the LED 100. The light emitting die 102 is a semiconductor chip that generates light of a particular peak wavelength. The light emitting die is typically made from Indium-doped Gallium Nitride (InGaN) epitaxial layer on a transparent sapphire substrate. Thus, the light emitting die 102 is a light source of the LED 100. Although the LED 100 shown in FIG. 1 as having only a single light emitting die, the LED may include multiple light emitting dies. The light emitting die 102 is attached or mounted on the upper surface of the lead frame 105 using an conductive die attach material 114, and electrically connected to the other lead frame 106 via the wire bond 108. The lead frames 105 and 106 are made of metal, and thus, are electrically conductive. The lead frames 105 and 106 provide the electrical power needed to drive the light emitting die 102.

In this embodiment, the lead frame 105 has a recessed reflector region 116 at the upper surface, which forms a reflector cup in which the light emitting die 102 is mounted. Since the light emitting die 102 is mounted on the lead frame 105, the lead frame 105 can be considered to be a mounting structure or substrate for the light emitting die. The surface of the reflector cup 116 may be reflective so that some of the light generated by the light emitting die 102 is reflected away from the lead frame 105 to be emitted from the LED 100 as light output.

The light emitting die 102 has a layer of phosphor material 110 disposed over it. The phosphor material 110 is generally a transparent epoxy resin containing particles of YAG:Ce phosphor. The entire assembly is embedded in a transparent encapsulation epoxy resin 112. If the light emitting die 102 emits a blue light, the phosphor particle is excited by the blue light to produce yellow light. As a result, the blue and yellow light are mixed to produce white light.

However, the layer of phosphor material 110 that is formed within the reflector cup 116 is then heat cured in the oven over a period of time. During the heat curing process, the phosphor particles tends to separate from the epoxy resin and settles around the light emitting die 102, creating two very distinct layer as shown in FIG. 2 on a larger scale. Accordingly, the thickness of the resin layer 110b and the phosphor layer 110a loses its uniformity, resulting in unwanted non-uniform color of light being produced.

To achieve the brightness expected today, one would need more than one light emitting dies or chips to match the light intensity produced by the conventional light sources, such as incandescent, halogen and fluorescent lamps.

Unfortunately, it is difficult to efficiently make white LEDs to produce homogenous light output to compete with the conventional light sources. The source of inefficiency lies in the method of having a consistent layer of phosphor coating on top of the light emitting chip. However, due to the settling problem experienced by the phosphor particles, the color of light produced does not consistently falls within the McAdam ellipse boundary of the (0.31,0.32) color coordinate on the 1931 CIE chromaticity diagram. The eyes are able to detect the color variation produced by those (x,y) color coordinates that fall outside of the boundary of the McAdam ellipse.

Another problem encountered is the intense power used. To achieve the brightness expected, one would need to match the efficacy produced by the current conventional light sources. Due to the intense heat generated by the light emitting dies during operation, those phosphor particles that are in proximity with the light emitting dies were found to be burnt.

To overcome the issue stated above, Lowery, U.S. Pat. No. 5,959,316, disclosed the method of dispensing a thick transparent resin layer over the blue light emitting die, and to apply a thin layer of resin containing phosphor particles over the transparent layer. In another prior art LED lamp 300 shown in FIG. 3, a light emitting die 302 mounted on a substrate 305 is covered with a transparent epoxy resin portion 303 on which a thin layer of phosphor 304 is dispersed. As a result, the color unevenness can be reduced significantly.

There are however two problems to this approach. Firstly, the uniformity of the phosphor coating is dependent of the shape of the transparent layer. The volume and thickness of the transparent layer is difficult to control, especially when the resin is dispensed and shrunk during the heat curing process, causing inconsistent thickness of the transparent layer. Secondly, the presence of the intervening transparent layer which separates the light emitting chip from the phosphor, causing an undesirable optical broadening effect.

Multiple light emitting chip (multichip) generally further increase the complexity of the multichip module. One design of such multichip module is disclosed in Baretz et. al., U.S. Pat. No. 6,600,175 where a phosphor contained in an encapsulant disposed inside the housing. The complexity of multichip is such that composition of the phosphor particles cannot be consistently controlled and evenly distributed over the array of light emitting chips. This unfortunately impacted the quality of the light output.

FIG. 4 shows a configuration of an LED lamp 400 in which multiple light emitting dies 402 having a structure shown in FIG. 3 are arranged in an array manner on a substrate 405. In the LED lamp 400, the transparent epoxy resin portion 403, each covering its associated light emitting die 402, are arranged in columns and rows on the substrate 405. By adopting such an arrangement, the luminous fluxes of a plurality of light emitting dies can be combined together. Thus, a luminous flux, comparable to that of an incandescent lamp, a fluorescent lamp or any other general illumination sources that is used extensively today, can be achieved easily.

Unfortunately thermally setting the transparent epoxy resin 403 to ensure consistent thickness covering the light emitting dies 402 is hard to control. The challenge to control both the transparent epoxy resin 403 and phosphor layer 404 becomes greater when a consistent thickness are required for all the light emitting dies 402 arranged in columns and rows on the substrate 405. It has been difficult to completely eliminate the color unevenness produced by the multiple chips. Customers view the variation of white as a defect in the multichip module. This predominantly reduces the yield in the manufacturing process which is of concern.

Another concern in the multichip module design is the effectiveness of heat being dissipated from the substrate where the multichip is mounted. When the heat is not effectively removed from the substrate, light emitting chips will degrade resulting in electrical and optical abnormality. This indirectly affects the light generated causing color variation in the point light source corresponding to the light emitting chips that have degraded. This uneven color distribution of light is an issue for the illumination applications.

As described in the conventional techniques above, the non-uniform color should have disappeared and a homogenous multichip module should have been realized. However this is untrue, and the non-uniform color produced by the multichip module still persists. The present invention contemplates improved apparatuses and methods that overcome the above mentioned limitations and others.

### SUMMARY OF THE INVENTION

Disclosed in this invention are methods that provide integrated solutions to achieve uniform brightness produced from the light sources, efficient light extraction and homogenous light emitted by the multichip module via shaping the light transmissive layer, phosphor layer and encapsulant; and placement of light sources on metal base substrate.

The process of shaping the light transmissive layer, phosphor layer and encapsulant can be achieved and formed using an injection molding process. The structural and processes disclosed in this invention can significantly improve production consistency, manufacturing cost efficiency, efficient light extraction and homogenous light emitted from the multichip module.

In accordance with the invention, a metal base substrate having a metallization pattern formed on it for mounting the light sources. A metal substrate has good thermal conductivity. If the substrate is an aluminum based type, an aluminum oxide layer may be formed on the surface to provide a dielectric layer substantially co-planar with the aluminum surface. A copper layers may be printed, sputtered, plated, or otherwise deposited on the dielectric layer.

The metallization is typically designed for interconnecting light emitting dies, light sources, or other heat-generating components that are ultimately mounted on the metal layers. The patterned metal layers (electrical tracks) may also include pads for connection to power supply leads.

The multichip module comprises a substrate which supports the array of light sources and having metal layers formed on the substrate. The array of light sources is arranged on the substrate along the metal layers and is electrically connected to the metal layers. The array of light sources may be connected in series or parallel or a combination of series and parallel. The anode and cathode ends of the series string are connected to separate metal pads for connection to a power supply.

In one embodiment, a multichip module comprises of light sources arranged in an array manner that the position of light sources are such that they are a distance of d₁ in the x-direction and d₂ in the y-direction apart, and d₁ and d₂ can be substantially equal or different from each other. Alternatively d₁ and d₂ can be spaced at different distances apart.

A light transmissive layer disposed on the substrate over the array of light sources having thickness t, measured from the top surface of the light source. If the light sources used are not flip-chip type light emitting dies but instead include one or more electrodes on top for wire bonding, the light transmissive layer disposed over the surface of the array of dies is substantially greater than or equal to 0.1 mm to ensure proper coverage of the wire loop. A light transmissive layer having a thickness of greater than or equal to 0.1 mm would also apply for flip-chip dies too. At the same time, the clearance ensures that all primary lights escaped from the light source can interact fully with the above phosphor layer.

A phosphor resin member made of a translucent resin including a phosphor material formed above the surface of the light transmissive layer.

The encapsulant material overlies the phosphor layer to encapsulate the array of light sources, and having a domed (e.g. a hemispherical shape) portion which acts as a lens. The light emitted from the phosphor layer is further collimated through the encapsulant material which acts as a lens.

According to another aspect of the invention, a method is provided in fabricating a multichip module. The substrate having a patterned metal layers (electrical tracks) formed over an oxidized region of the metal substrate. Arranging light sources in an array manner along the metal layers on the substrate. The light sources are then electrically connected to the metal layers. The array of light sources may be connected in series or parallel or a combination of series and parallel. The anode and cathode ends of the series string are connected to separate metal pads for connection to a power supply.

In one embodiment, the method of fabricating a multichip module where the light sources are arranged in an array manner and positioned such that they are a distance of d₁ in the x-direction and d₂ in the y-direction apart, and d₁ and d₂ can be substantially equal or different from each other. Alternatively d₁ and d₂ can be spaced at different distances apart.

The light transmissive layer is molded into a desired shape to match the radiation pattern of the light sources. The molded light transmissive layer having a thickness greater than or equal to 0.1 mm measured from the top surface of the light sources to ensure full coverage of the wire loop.

In another aspect where the light sources do not exhibit any wire loop, the molded transmissive layer retains the thickness of greater than or equal to 0.1 mm to ensure that all primary lights escaped from the light source can fully interact with the molded phosphor layer.

Depending on the light transmissive material, the method can further comprise curing the light transmissive material by thermal curing prior to removing the mold used to shape the light transmissive layer.

A phosphor resin member is further molded over the light transmissive layer, where it acts as a lens to improve the light output and minimize light losses. The phosphor resin member can take on the shape that is different from the light transmissive layer or conform to it. The phosphor resin material is further cured prior to removing the mold.

The final fabrication step is to mold the encapsulant material in a shape of a dome where it acts as a primary lens to re-direct the light emitted from the light sources.

The light transmissive layer, phosphor resin layer and encapsulant lens may be formed via injection molding, compression mold, casting, or any other suitable method that forms and shapes the material.

Other aspects and advantages of the present invention will become apparent to those skilled in the art from the following detailed description, taken in conjunction with the accompanying drawings, illustrated by way of example of the principles of the invention.

### BRIEF DESCRIPTION OF THE DRAWINGS

In order that the present invention is better understood, embodiments of the invention will now be described. The drawings are only for the purposes of illustrating preferred embodiments and are not to be construed as limiting the invention.

FIG. 1 is a cross-sectional view of a light emitting diode (LED) in accordance with the prior art.

FIG. 2 is an enlarged cross-sectional view of a prior art LED illustrating the main portion of its encapsulation system.

FIG. 3 is a close-up view of a prior art LED in a surface-mount device and its encapsulation system in accordance with an alternative embodiment.

FIG. 4 is a perspective view illustrating an exemplary configuration in which multiple LED lamp having the structure shown in FIG. 3 are arranged in a matrix.

FIG. 5 shows a cross sectional view of a metal substrate of a multichip module in which light emitting dies is mounted. A light transmissive layer covering the light emitting dies and a phosphor layer molded on the surface of the light transmissive layer. An encapsulant lens over molding the dies, light transmissive layer and phosphor layer forming the module.

FIG. 6 shows a perspective view of a metal substrate with copper vias extending from the top surface to the bottom surface of the substrate of a multichip module.

FIG. 7 shows a top view of multichip module having light emitting dies arranged in an array manner. The light emitting dies are position in an array manner such that they are a distance of d₁ in the x-direction and d₂ in the y-direction apart from each other which is critical to achieve a homogeneous light output from the multichip module.

FIG. 8A-8C shows a side sectional view of multichip modules where top light emitting dies is employed. The light transmissive layer is molded in the form of a square or rectangular shape to match the radiation pattern of the light emitting dies. FIG. 8A-8C shows the alternative configurations of the molded phosphor resin. FIG. 8A exhibits an elliptically shaped molded phosphor resin. FIG. 8B exhibits a dome shaped molded phosphor resin and FIG. 8C exhibits a thin rectangular of molded phosphor layer. The light transmissive layer, phosphor layer and light emitting dies are then encapsulated over by a dome shape encapsulant material which acts as a lens

FIG. 9 shows a side sectional view of a multichip module where light emitted from the top and all four sides of the light emitting dies are adopted. The light transmissive layer and phosphor resin member are both configured and molded in the shape of a dome to match the radiation pattern of the light emitting dies. An encapsulant material having a dome shaped that functions as a lens encapsulating the phosphor resin member, light transmissive layer and light emitting dies.

FIG. 10 is a process flow diagram of a method for making a multichip module in accordance with an embodiment of the invention.

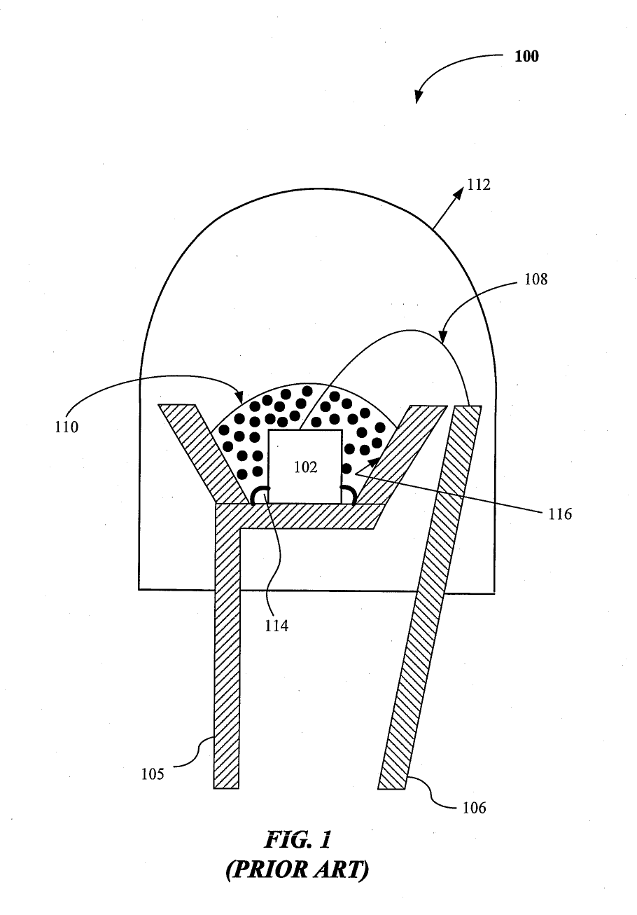

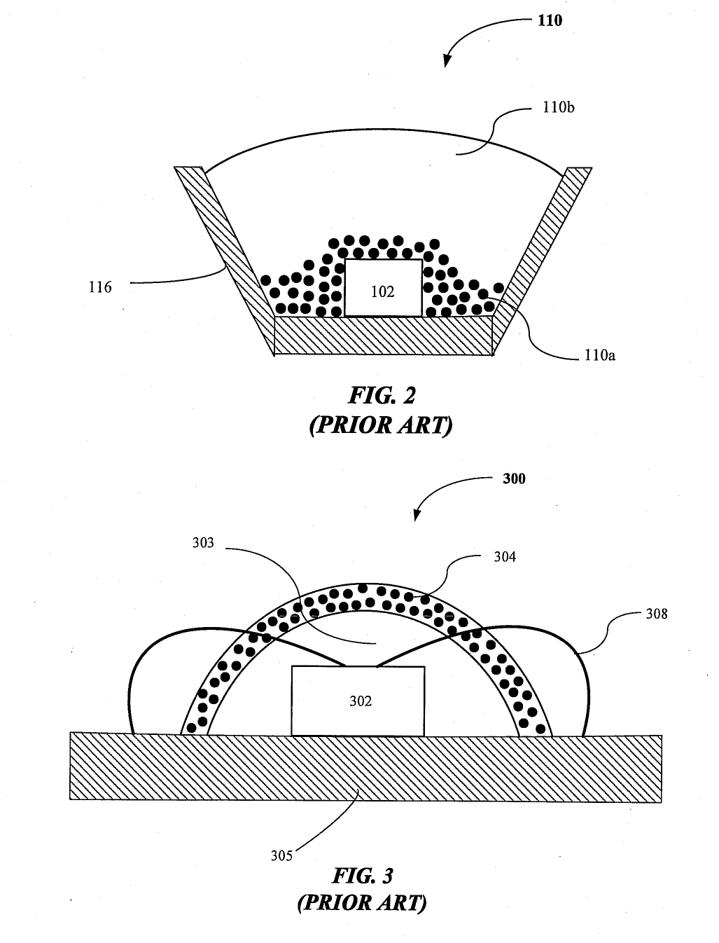

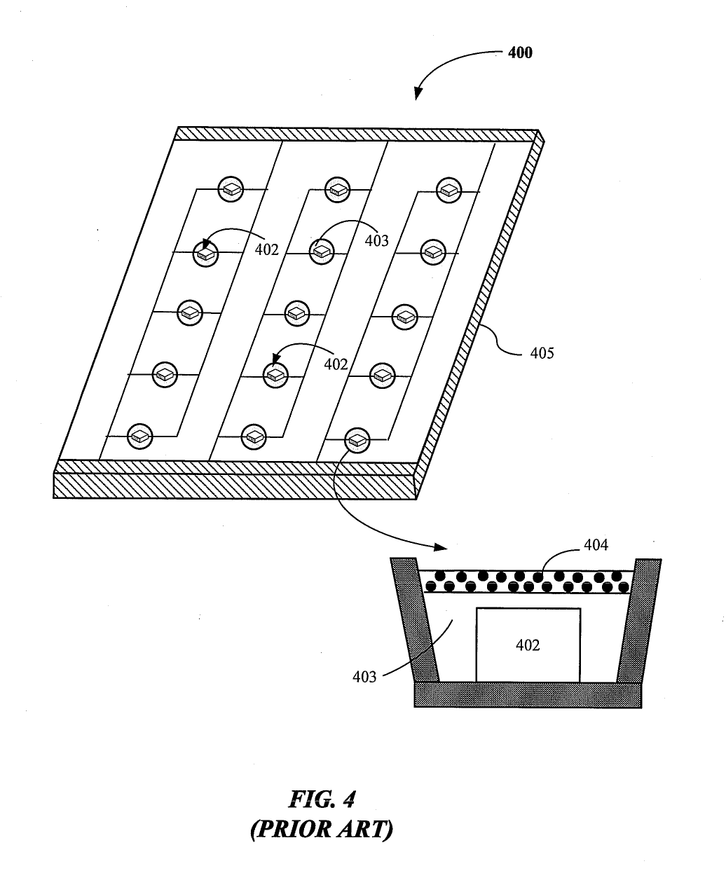

### DETAILED DESCRIPTION

In order to overcome the problems described above, the primary objective of this invention is to provide a method for fabricating a multichip module that causes significantly reduced color unevenness. Another object of the present invention is to provide a multichip module that causes significant reduction of color unevenness.

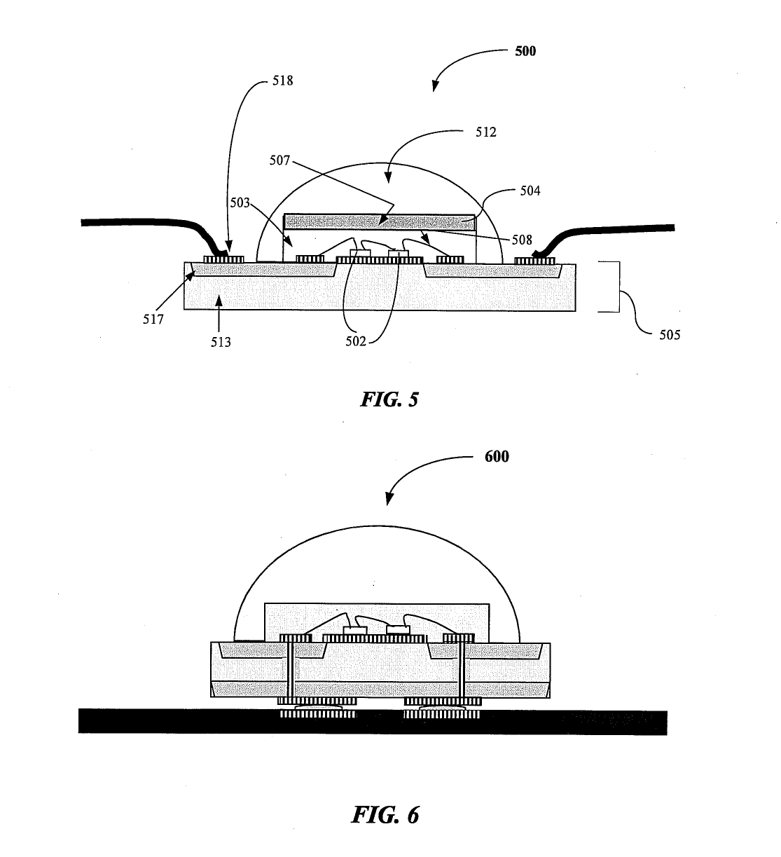

FIG. 5 illustrates a cross-sectional view of a multichip module 500 which includes a substrate 505, on which a series of light emitting dies 502 are arranged in a planar array. A substrate 505 may be aluminum based; a dielectric layer 517 for supporting metal electrode pads 518 is formed by selective oxidation of the aluminum surface by masking and anodizing (oxidation). The aluminum oxide 517 is slightly porous, and the porosity of the aluminum oxide is beneficial for strongly bonding a copper layer 518 that has been sputtered directly onto the oxide surface. Such an oxide layer will be substantially co-planar with the remainder of the aluminum based surface. Other types of substrates can also be used.

For anodizing portions of an aluminum based substrate 505, the aluminum 513 is masked using conventional lithography techniques. The exposed portions are anodized by immersing the aluminum in an electrolytic solution and applying current through the aluminum and the solution. Oxygen is released at the surface of the aluminum, producing an aluminum oxide layer 517 having nanopores. The aluminum oxide layer 517 may be formed to any depth. Aluminum oxide is ceramic in nature and is a highly insulating dielectric material with a thermal conductivity between 20-30 W/mk. The aluminum oxide layer 517 can be made thin so as not to add significant thermal resistance. The unexposed aluminum substrate has very high thermal conductivity on the order of 250 W/mk. This is critical to ensure effective removal of heat that is generated by the array of light emitting dies 502 mounted on it.

A resin (a polyimide) is then diffused into the porous aluminum oxide layer to planarize the surface.

The patterned metal layers/electrical conductive layers 518, for bonding the light emitting dies, is later formed over the oxide portions. The metal layer 518 can be printed on, sputtered, or otherwise deposited on the dielectric layer on the substrate. The metal layers 518 comprises of copper.

Patterning copper layer over an aluminum oxide layer in an aluminum based substrate is sometimes described as an ALOX™ process. ALOX™ is a trade name coined by Micro Components, Ltd to identify an aluminum substrate with an oxidized surface portion and a copper layer (or other metal layer to aid soldering) deposited on the oxidized surface. Forming ALOX™ substrates is described in US patent application publication US 2007/0080360 and PCT International Publication Number WO 2008/123766, both incorporated herein by reference.

Typically, metal/electrical pads 518 are formed on aluminum oxide surface 517 to electrically connect the dies with patterned metal traces 518. The dies 502 can be mechanically and electrically attached to the ALOX™ substrate 505 in a variety of ways, such as: by soldering the dies 502 to the ALOX™ substrate 505 and using wire bonds 508 to electrically connect the die electrodes with metal pads 518 of the ALOX™ substrate 505; flip-chip bonding of dies electrodes to electrical pads 518 of ALOX™ substrate 505; or so forth. The ALOX™ substrate 505 would efficiently and effectively remove the heat produced by the multiple dies 502 that are mounted onto its ALOX™ substrate 505. This prevents heat from accumulating on the ALOX™ substrate 505 when dies 502 are in operation. When the heat is not effectively removed, light emitting dies 502 will degrade resulting in electrical and optical abnormality. This is one of the factors that affect the overall quality of light generated. By eliminating this variant would ensure homogenous light produced by the array of multiple dies 502 which is important in the illumination applications.

The described multichip module 500 which includes a single sided metal layer ALOX™ substrate 505 structure is an example. Other support structure of multichip module 600 with a double sided metal layer ALOX™ substrate shown in FIG. 6 can also be employed. For example, the patterned metal traces can be disposed on the die attach surface and on the bottom surface.

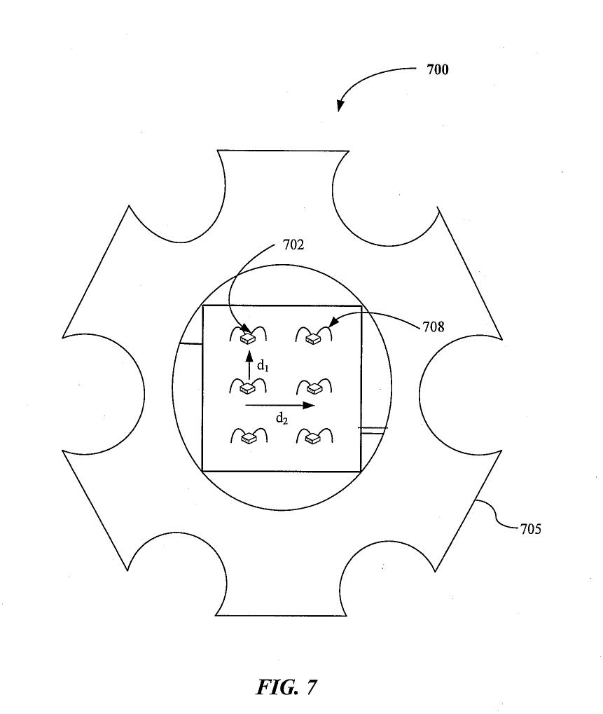

In multichip module 700 with reference to FIG. 7 (not to scale), the placement and mounting of light emitting dies 702 onto ALOX™ substrate 705, arranged in an array manner such that they are a distance of d₁ in the x-direction and d₂ in the y-direction apart from each other. The light emitting dies 702 are arranged on the ALOX™ substrate 705 along the metal layers (electrical tracks) and may be connected in series or parallel or a combination of series and parallel to the electrical tracks. The position of the light emitting dies 702 placed in a distance of d₁ and d₂ apart from each other is critical to achieve a homogenous light produced by the multichip module 700. The placement of the light emitting dies 702 d₁ and d₂ apart from each other can be substantially equal or different from each other. Alternatively d₁ and d₂ can be spaced at different distances apart. Preferably, the distance d₁ and d₂ is substantially equal to each other.

With continuing reference to FIG. 5, the multichip module 500 further include a light transmissive layer 503 disposed over the light emitting dies 502. The light transmissive layer 503 can be secured to the ALOX™ substrate 505 by means of a molding process where it is molded into a desired shape depending on the type and shape of dies used to match the radiation pattern of the light emitting dies 502. The molded light transmissive layer 503 having a thickness t greater than or equal to 0.1 mm measured from the top surface of the light emitting dies 502 to ensure full coverage of the wire loop 508. The light transmissive layer 503 retains the thickness t of greater than or equal to 0.1 mm to ensure all primary blue lights generated from the light emitting dies 502 escape from the dies to fully interact with the molded phosphor resin member 504. Depending on the light transmissive material used, the method can further comprise curing the light transmissive material by thermal curing prior to removing the mold used to shape the light transmissive layer. The light transmissive material can be made of any optically transparent material. As an example, the light transmissive layer 503 can be made of epoxy, silicone, or a hybrid of silicone and epoxy system.

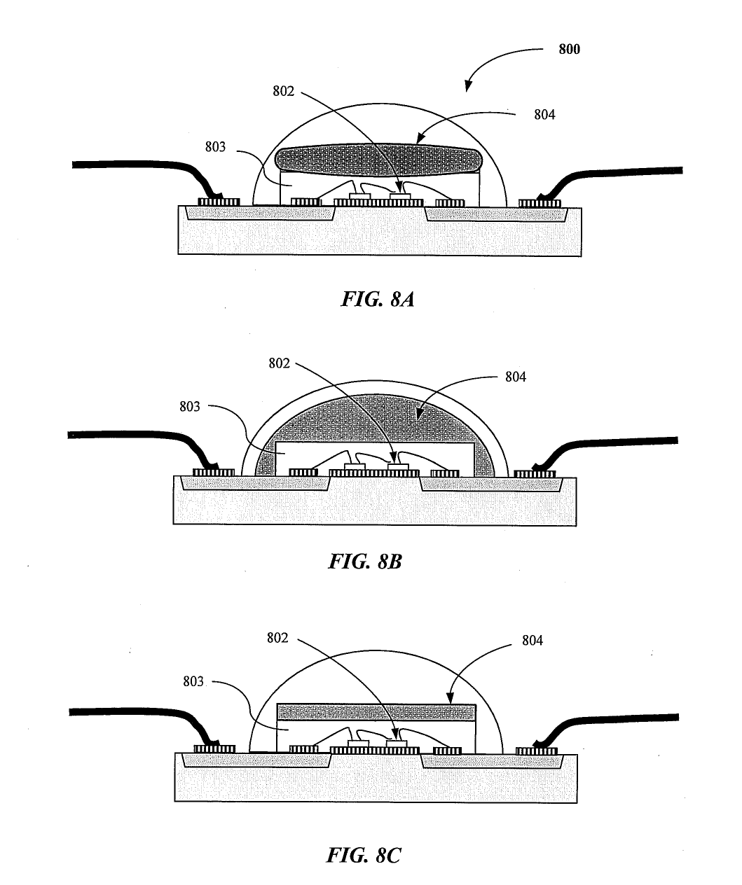

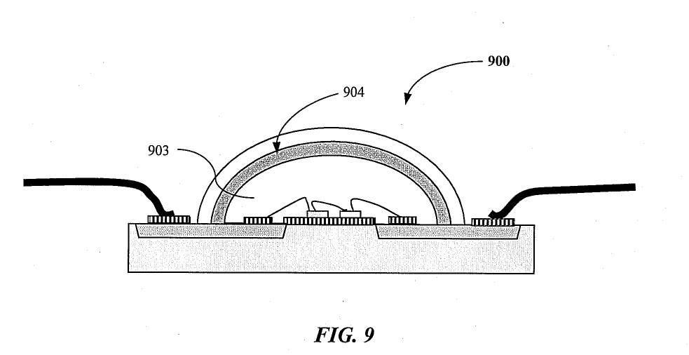

A molded phosphor resin member 504 is further molded over the light transmissive layer 503 where it acts as a secondary lens to improve the light output and minimize light losses. The phosphor resin member 503 can take on the shape that is different from the light transmissive layer or conform to it. Different shapes of molded light transmissive layer and molded phosphor resin member are further illustrated in FIGS. 8A-8C and 9. The phosphor resin material is further cured prior to removing the mold.

The phosphor 507 that is disposed within the phosphor resin member 504 is selected to produce the desired wavelength conversion of a portion or substantially all of the light produced by the light emitting dies 502. The term “phosphor” is to be understood as including a single phosphor compound or a phosphor blend or composition which consists of two or more phosphor compound chosen to produce a selected wavelength conversion. For example, the phosphor 507 may be a single phosphor compound or a phosphor blend including yellow, yellow/green, red, green, orange, blue phosphors and combination thereof. The phosphor resin member 503 is generally phosphor particles 507 disposed within the transparent resin material which can be selected from epoxy, silicone, or a hybrid of silicone and epoxy system.

The light emitting die being semiconductor device consists of more than one semiconductor layers having top surface and a bottom surface. Depending on the type of dies employed, the light emitted may be from the top surface or from both top and all four sides of the light emitting die. For top light emitting dies, the light transmissive layer 803 is configured as a square or rectangular shape to match the radiation pattern of the light emitting dies 802. This is to ensure all light emitted from the light emitting dies 802 escape and enters the phosphor resin member 804. FIGS. 8A-8C shows the alternative ways to configure the molded phosphor resin member 804. The phosphor resin member 804 can be molded over the light transmissive layer 803 in various ways, such as thin square layer; thin rectangular layer; dome (e.g. a hemispherical) shaped; or elliptically shaped; or so forth. The described shapes of the molded phosphor resin member 804 are examples and are not limited to those described above.

Alternatively, for both top and sides light emitting dies, as illustrated in FIG. 9, the light transmissive layer 903 is be configured and molded in a shape of a dome. The phosphor resin member 904 is further molded over the light transmissive layer 903 to conform to its shape.

Continuing reference to FIG. 5, the multichip module 500 further includes an encapsulation material 512 that overlay the phosphor resin member 504 that encapsulates the array of light emitting dies 502 where the encapsulant having a dome shaped that functions as a lens. The encapsulation material 512 may be formed using an injection molding, compression mold, casting process, or any other suitable methods to form and shape the dome. The domed encapsulant eliminates the need to attach a lens, and thus, resolves quality issues associated with an attached lens. The domed encapsulant 512 can be made of any optically transparent material. As an example, the domed encapsulation 512 can be made of epoxy, silicone, a hybrid of silicone and epoxy system, amorphous polyamide resin or fluorocarbon, glass and/or plastic material.

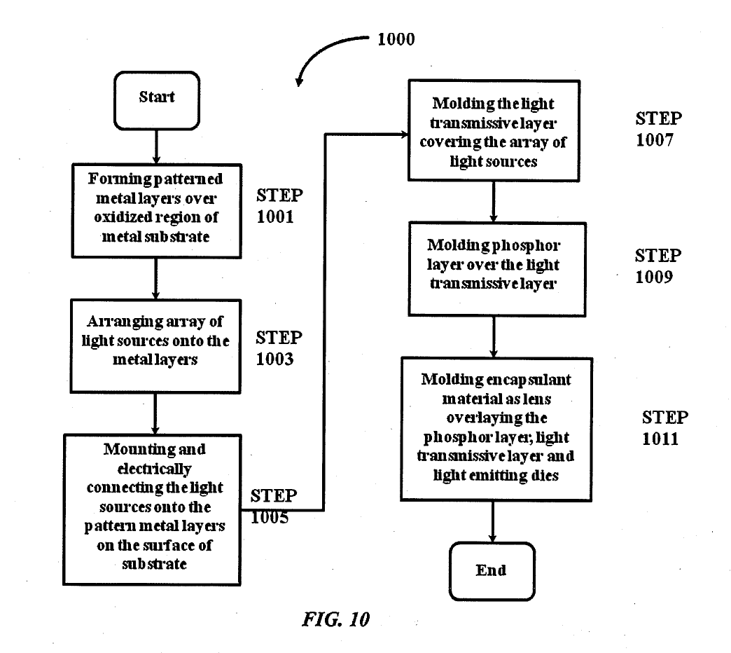

A fabrication process for producing a multichip module 500 of FIG. 5 in accordance with an embodiment of the invention is described with reference to FIG. 10, as well as FIG. 5. As illustrated in STEP 1001, the fabrication process begins with forming patterned metal layers 518 over oxidized region 517 of the metal substrate 513. In STEP 1003, light emitting dies 502 is arranged in an array manner such that they are a distance of d₁ in the x-direction and d₂ in the y-direction apart from each other, and d₁ and d₂ can be substantially equal or different from each other. Alternatively d₁ and d₂ can be spaced at different distances apart. In STEP 1005, the light emitting dies 502 are mounted onto the pattern metal layers 518 on the surface of ALOX™ substrate 505 using an Ag paste, carbon paste, metallic bump or the like can be used. The light emitting dies 502 are wire bonded to the metal/electrical pads 518 to electrically connect the dies with patterned metal layers 518. The array of light sources may be connected in series or parallel or a combination of series and parallel. The anode and cathode ends of the series string are then connected to separate metal pads for connection to a power supply. In STEP 1007, a light transmissive layer 503 is molded over the light emitting dies 502, and the wire bond 508. Preferably, the light transmissive layer 503 can be made of epoxy, silicone, or a hybrid of silicone and epoxy system.

In the first embodiment where top light emitting die is employed, the light transmissive layer 503 is molded in a shape of a square or rectangular to match the radiation pattern of the light emitting dies 502. The phosphor resin layer 508 is then formed over the light transmissive layer 503 using injection molding process, as illustrated in STEP 1009. In this embodiment, the phosphor resin layer 508 can be molded in various shapes such as thin square layer, thin rectangular layer, dome shaped, or elliptically shaped, or so forth.

In a second embodiment where a top and sides light emitting dies is employed, the light transmissive layer and phosphor resin layer are both molded in a dome shape.

In the next step, as illustrated in STEP 10011, the domed encapsulant 512 is formed overlaying the phosphor resin layer 508. The domed encapsulant 512 can be made of any optically transparent material. Preferably, the domed encapsulant 512 can be made of epoxy, silicone, a hybrid of silicone and epoxy system, amorphous polyamide resin or fluorocarbon, glass and/or plastic material. The domed encapsulant 512 is formed in a single processing step. Since the domed or lens portion of the encapsulant 512 is an integral part of the encapsulant, there is no lens attachment issue for the resulting module. The light transmissive layer 503, phosphor resin layer 508 and domed encapsulant 512 are formed using an injection molding process. However, in other embodiments, the light transmissive layer 503, phosphor resin layer 508 and domed encapsulant 512 may be formed using a different fabrication procedure and not limited to injection molding process. The finished multichip module 500 is produced, as shown in FIG. 5.

What is claimed is:

1. A multichip module comprising:
a substrate that is metal base type with metal oxide layer formed on the surface to provide a dielectric layer substantially co-planar with the metal surface;
patterned metal layer formed on the dielectric layer of the substrate;
an array of light sources being mounted and electrically connected to the metal layers;
a light transmissive layer disposed over said array of light sources;
a layer of phosphor resin formed above the surface of the said light transmissive layer;
an encapsulant material overlaying the phosphor resin to encapsulate the said array of light sources, and said encapsulant having a portion shaped as a lens to focus light emitted by the array of light is sources.

2. The multichip module of claim 1 wherein metal base substrate comprises of aluminum.

3. The multichip module of claim 1 wherein patterned metal layer comprises pads for electrical connection, and one or more pads for mounting the light sources.

4. The multichip module of claim 1 wherein pattern metal layer comprises of copper.

5. The multichip module of claim 1 wherein the light sources arranged in a planar array, separated by a distance d₁ in the x-direction and d₂ in the y-direction apart.

6. The multichip module of claim 1 wherein said array of light sources are light emitting dies.

7. The multichip module of claim 6 wherein said array of light emitting dies emits light from the top surface of the dies.

8. The multichip module of claim 1 wherein said light transmissive is layer disposed over said array of light sources having a thickness t measured from the surface of the light sources.

9. The multichip module of claim 1 wherein said light transmissive layer includes material selected from a group consisting of epoxy, silicone, and a hybrid of silicone and epoxy.

10. The multichip module of claim 1 wherein said phosphor resin forms a rectangular or square shape above the surface of the said light transmissive layer.

11. The multichip module of claim 1 wherein said phosphor resin forms an ellipsoidal shape above the surface of the said light transmissive layer.

12. The multichip module of claim 1 wherein said phosphor resin is in the shape of a dome, formed above the surface of the said light transmissive layer.

13. The multichip module of claim 1 wherein said phosphor is selected from the group consisting of yellow phosphors, yellow/green phosphors, red phosphors, green phosphors, orange phosphors, blue phosphors, and combinations thereof.

14. The multichip module of claim 1 wherein the said encapsulant includes material selected from a group consisting of epoxy, silicone, a hybrid of silicone and epoxy, amorphous polyamide resin or fluorocarbon, glass and plastic.

15. A multichip module comprising:
a substrate that is metal base type with metal oxide layer formed on the surface to provide a dielectric layer substantially co-planar with the metal surface;
patterned metal layer formed on the dielectric layer of the substrate;
an array of light sources being mounted and electrically connected to the metal layers;
a light transmissive layer formed having a shape of a dome covering said array of light sources;
a layer of phosphor resin conforming to the shape of the light transmissive layer;
an encapsulant material overlaying the phosphor resin to encapsulate the said array of light sources, and said encapsulant having a portion shaped as a lens to focus light emitted by the array of light sources.

16. The multichip module of claim 15 wherein the metal base substrate comprises of aluminum.

17. The multichip module of claim 15 wherein patterned metal layer comprises pads for electrical connection, and one or more pads for is mounting the light sources.

18. The multichip module of claim 15 wherein pattern metal layer comprises of copper.

19. The multichip module of claim 15 wherein the light sources arranged in a planar array, separated by a distance d₁ in the x-direction and d₂ in the y-direction apart.

20. The multichip module of claim 15 wherein said array of light sources are light emitting dies.

21. The multichip module of claim 20 wherein said array of light emitting dies emit light from the top and all four sides of the dies.

22. The multichip module of claim 15 wherein said light transmissive layer includes material selected from a group consisting of epoxy, silicone and a hybrid of silicone and epoxy.

23. The multichip module of claim 15 wherein said phosphor is selected from the group consisting of yellow phosphors, yellow/green phosphors, red phosphors, green phosphors, orange phosphors, blue phosphors, and combinations thereof.

24. The multichip module of claim 15 wherein the said encapsulant is includes material selected from a group consisting of epoxy, silicone, a hybrid of silicone and epoxy, amorphous polyamide resin or fluorocarbon, glass and plastic.

25. A method for fabricating a multichip module, said method comprising:
providing a substrate that is metal base type with metal oxide layer formed on the surface to provide a dielectric layer which is substantially co-planar with the metal surface;
forming patterned metal layer on the dielectric layer of the substrate;
mounting the light sources and electrically connecting the light sources to the metal layers;
forming a light transmissive layer disposed over said array of light sources;
forming a layer of phosphor resin above said light transmissive layer;
forming an encapsulant overlaying said array of light sources and said substrate, said encapsulant having a portion shaped as a lens to focus light emitted by the array of light sources.

26. The method of claim 25 wherein said metal base substrate comprises of aluminum.

27. The method of claim 25 wherein said patterned metal layer forms is pads for electrical connection, and one or more pads for mounting the light sources.

28. The method of claim 25 wherein said formed pattern metal layer comprises of copper.

29. The method of claim 25 wherein said light sources are formed and bonded in a planar array, separated by a distance d₁ in the x-direction and d₂ in the y-direction apart.

30. The method of claim 25 wherein said array of light sources are light emitting dies.

31. The method of claim 30 wherein said array of light emitting dies emits light from the top surface of the dies or are flip-chip dies.

32. The method of claim 25 wherein said forming said light transmissive layer includes performing an injection molding process to form said light transmissive layer over said array of light sources having a thickness t measured from the surface of the light sources.

33. The method of claim 25 wherein said forming a layer of said phosphor resin includes performing an injection molding process to form a layer of phosphor resin in the shape of a rectangle or square above the surface of the said light transmissive layer.

34. The method of claim 25 wherein said forming said phosphor resin includes performing an injection molding process to form an ellipsoidal shape above the surface of the said light transmissive layer.

35. The method of claim 25 wherein said forming said phosphor resin includes performing an injection molding process to form a dome shape of the phosphor resin above the surface of the said light transmissive layer.

36. The method of claim 25 wherein said forming said encapsulant includes performing an injection molding process to form said encapsulant.

37. A method for fabricating a multichip module, said method comprising:
providing a substrate that is metal base type with metal oxide layer formed on the surface to provide a dielectric layer which is substantially co-planar with the metal surface;
forming patterned metal layer on the dielectric layer of the substrate;
mounting the light sources and electrically connecting the light sources to the metal layers;
forming a light transmissive layer having a shape of a dome over said array of light sources;
forming a layer of phosphor resin that conforms to the shape of said light transmissive layer;
forming an encapsulant overlaying said array of light sources and said substrate, said encapsulant having a portion shaped as a lens to focus light emitted by the array of light sources

38. The method of claim 37 wherein said metal base substrate comprises of aluminum.

39. The method of claim 37 wherein said patterned metal layer forms pads for electrical connection, and one or more pads for mounting the light sources.

40. The method of claim 37 wherein said formed pattern metal layer comprises of copper.

41. The method of claim 37 wherein said light sources are formed and bonded in a planar array, separated by a distance d₁ in the x-direction and d₂ in the y-direction apart.

42. The method of claim 37 wherein said array of light sources are light emitting dies.

43. The method of claim 42 wherein said array of light emitting dies emit light from the top and all four sides of the dies.

44. The method of claim 37 wherein said forming said light transmissive layer includes performing an injection molding process to form the shape of a dome over said array of light sources.

45. The method of claim 37 wherein said forming a layer of said phosphor resin includes performing an injection molding process to form a conformal coating over the surface of the light transmissive layer.

46. The method of claim 37 wherein said forming said encapsulant includes performing an injection molding process to form said encapsulant.
